(19) United States
(12) Patent Application Publication
(10) Pub. No.: US 2025/0029887 A1
(43) Pub. Date: Jan. 23, 2025

(54) CIRCUIT BOARD ASSEMBLY AND METHOD

(71) Applicant: Vitesco Technologies GmbH, Regensburg (DE)

(72) Inventors: Andreas Mühlbauer, Bernhardswald (DE); Detlef Haupt, Regenstauf / Steinsberg (DE)

(73) Assignee: Vitesco Technologies GmbH, Regensburg (DE)

(21) Appl. No.: 18/776,459

(22) Filed: Jul. 18, 2024

(30) Foreign Application Priority Data
Jul. 20, 2023 (DE) 102023206893.1

(51) Int. Cl. H01L 23/367; H01L 23/00; H05K 1/18; H05K 3/30

(52) U.S. Cl. CPC H01L 23/367; H01L 24/32; H05K 1/181; H05K 3/303; H01L 2224/32245

(57) ABSTRACT

A circuit board assembly, which includes an insert, a printed circuit board (PCB), the insert connected to the PCB, at least one semiconductor device, a primary connection between the insert and the semiconductor device, and a secondary connection between the insert and the semiconductor device. The secondary connection provides electrical and thermal communication between the semiconductor device and the insert when the primary connection fails. The primary connection between the insert and the semiconductor device is a sintered connection. The insert and the semiconductor device are in electrical and thermal communication with one another through the sintered connection. The sintered connection includes a sintering compound which connects the insert and the semiconductor device. The secondary connection includes a limp-home function if the primary connection fails.

### CROSS REFERENCE TO RELATED APPLICATIONS

This application claims priority to German Patent Application No. 102023206893.1, filed Jul. 20, 2023, the contents of such application being incorporated by reference herein.

### FIELD OF THE INVENTION

The invention relates to a circuit board assembly and a method for providing the same. The invention relates to a circuit board assembly having at least one semiconductor device and an insert, where the semiconductor device is connected to the insert using a primary connection and a secondary connection, such that if the primary connection fails, the secondary connection still provides electrical and thermal communication between the semiconductor device and the insert.

### BACKGROUND OF THE INVENTION

Vehicles typically include the use of some type of power module to perform various functions. Power modules typically include an integrated circuit (IC) in an enclosed module. Power modules having lower power requirements may have discrete components mounted on a printed circuit board (PCB). The arranged IC must be connected to these discrete components, and also include some type of enclosure to protect the IC. The enclosure may be in the form of a gel, overmolding, or the like. Manufacturing a power module having this type of enclosure results in a high level of complexity.

If discrete components are used on PCBs, the current carrying capacity of the component is usually limited by how the discrete component is connected to the PCB, such as through the use of pins. In this case, it is also not possible to produce optimal heat dissipation when using the discrete component on a PCB, as pin connections are known to have poor heat conduction (i.e, at approx. 0.3-0.5 W/mK).

### SUMMARY OF THE INVENTION

Accordingly, there exists a need for a connection between at least one discrete component and a PCB which provides sufficient heat dissipation and current carrying capacity.

Therefore, an aspect of the invention aims to provide a circuit board assembly, having a connection between at least one discrete component, such as a semiconductor device, and a PCB which eliminates the above-mentioned drawbacks of complexity, current-carrying capacity, and heat dissipation.

In an embodiment, the present invention is a circuit board assembly which reduces complexity in manufacturing, allowing for the use of an IC having various discrete components, such as a semiconductor device, which are enclosed and have defined connections. The handling of the discrete components is also simplified, as the semiconductors have already been removed from the wafer and are already enclosed. Therefore, only minor electrostatic discharge (ESD) measures are necessary to protect the semiconductor device during handling and assembly. In order to achieve a high current-carrying capacity, the circuit board assembly of an aspect of the present invention includes the integration of one or more discrete components into the circuit via the drain pin, and also to includes the use of the large rear side protrusion (i.e., tab) for this purpose. In order to facilitate the desired heat dissipation, the PCB includes one or more apertures. An insert made of a material with a high thermal conductivity coefficient and high current-carrying capacity (e.g., copper), is at least partially inserted into at least one of the apertures. The connection between the PCB and the insert may be achieved in any suitable manner. The insert may be held in place relative to the PCB because of the connection between the PCB and the semiconductors, or the insert may be connected to the PCB by a press-in operation or a press-fit connection, the use of a fastener such as a screw, or with any other interconnection technology. The semiconductors are connected to the PCB, e.g. by sintering or soldering. This ensures good heat dissipation and facilitates electrical communication. The discrete components, comprising the semiconductor devices, are at least partially positioned on the insert, where portions of the insert are inserted into the apertures of the PCB, and the insert is connected to the PCB. This connection is typically achieved by soldering or sintering in order to transfer the current from the PCB to the discrete components, such as the insert and semiconductor device. In an embodiment, a layer of a sintering compound is attached to the insert, which is used to achieve a flat, current-carrying connection with the PCB. In an embodiment, the PCB has a complementary copper geometry, possibly with an Au or Ag coating. In addition, one embodiment of the circuit board assembly includes an insert, which has defined areas, or protrusions, which may be inserted into the PCB. These protrusions also at least partially extend through the PCB, and the drain pins may be soldered onto a mounting surface of one or more of the corresponding protrusions of the insert. This further increases the current-carrying capacity, or, if the flat, current-carrying connection fails, act as limp home functionality. Emergency operation is ensured when lower currents are used.

In an embodiment, the present invention is a circuit board assembly, which includes an insert, a printed circuit board (PCB), the insert connected to the PCB, at least one semiconductor device, a primary connection between the insert and the semiconductor device, and a secondary connection between the insert and the semiconductor device. In an embodiment, the secondary connection provides electrical communication between the semiconductor device and the insert when the primary connection fails.

In an embodiment, the primary connection between the insert and the semiconductor device is a sintered or soldered connection. The insert and the semiconductor device are in electrical and thermal communication with one another through this connection.

In an embodiment, the sintered connection includes a sintering or soldering compound which connects the insert and the semiconductor device.

In an embodiment, the secondary connection includes a limp-home function if the primary connection fails.

In an embodiment, the secondary connection between the insert and the semiconductor device includes a solder connection.

In an embodiment, at least one protrusion is integrally formed as part of the insert, where the protrusion is part of the primary connection. At least one aperture is integrally formed as part of the PCB, and the protrusion at least partially extends into the aperture when the insert is assembled to the PCB.

In an embodiment, at least one bar is integrally formed as part of the insert, at least one extension is integrally formed as part of bar, the extension being part of the secondary connection, and a second aperture integrally formed as part of the PCB. The extension integrally formed as part of the bar at least partially extends into the second aperture when the insert is assembled to the PCB.

In an embodiment, an outer mounting surface of the protrusion, a mounting surface of the extension, and the outer surface of the PCB are in the same plane relative to one another.

In an embodiment, the present invention is a method for providing multiple connections between an insert and at least one semiconductor device of a circuit board assembly. The method includes the steps of providing an insert, providing a printed circuit board (PCB), and providing at least one semiconductor device. The method also includes the steps of connecting the insert to the PCB, connecting the insert to the semiconductor device such that there is a primary connection between the insert and the semiconductor device, and a secondary connection between the insert and the semiconductor device. The method also includes the steps of operating the circuit board assembly using a limp-home function with the secondary connection if the primary connection fails.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

Aspects of the present invention will become more fully understood from the detailed description and the accompanying drawings, wherein:

FIG. 1 is a top view of part of a circuit board assembly, according to embodiments of the present invention;

FIG. 2 is a bottom view of a semiconductor device which is part of a circuit board assembly, according to embodiments of the present invention;

FIG. 3 is a sectional view of taken along line 3-3 of FIG. 1;

FIG. 4A is a side view of an insert which is part of a circuit board assembly, according to embodiments of the present invention;

FIG. 4B is top view of an insert which is part of a circuit board assembly, according to embodiments of the present invention; and

FIG. 5 is a perspective view of an insert which is part of a circuit board assembly, according to embodiments of the present invention.

### DETAILED DESCRIPTION OF EXEMPLARY EMBODIMENTS

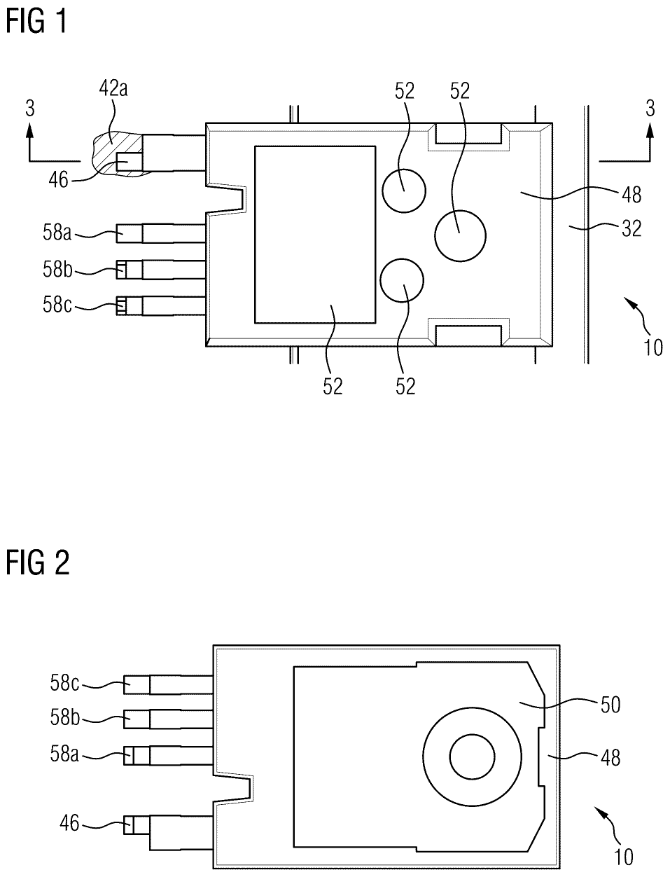

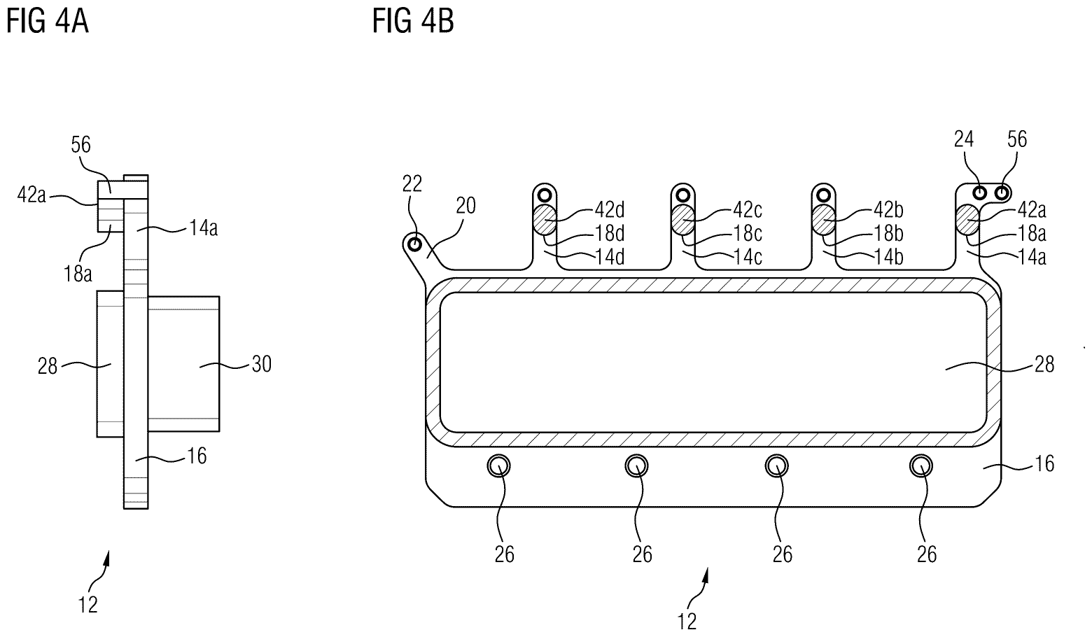

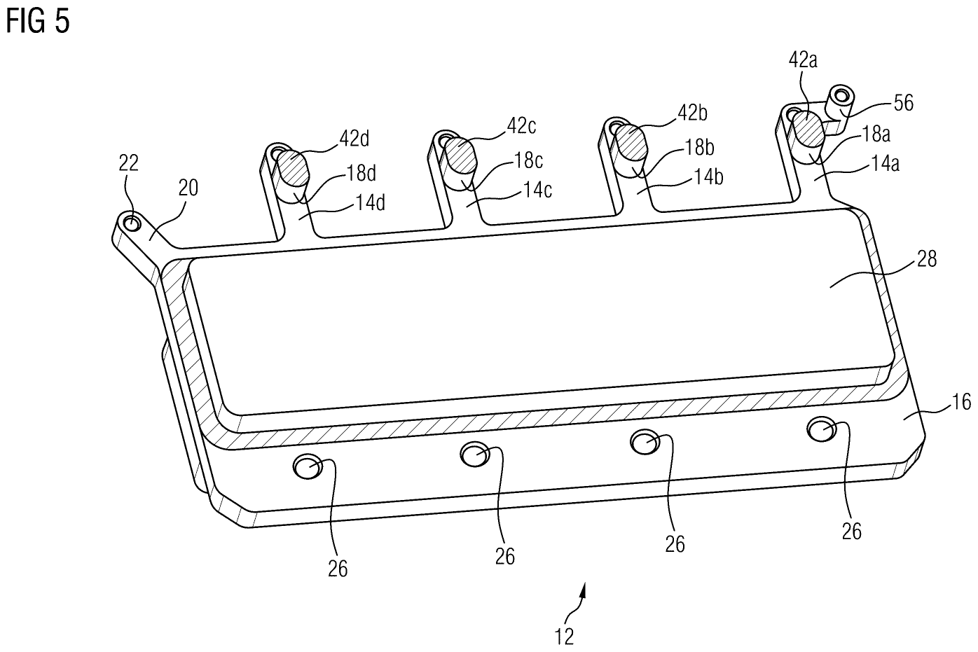

An embodiment of a circuit board assembly having various connecting features according to the present invention is shown in FIG. 1, generally at 10. Referring to the Figs. generally, the circuit board assembly 10 includes an insert, shown generally at 12. The insert 12 includes several bars 14a, 14b, 14c, 14d, shown in FIG. 4B and 5, which are connected to various components of the circuit board assembly 10. More specifically, in the embodiment shown the circuit board assembly 10 includes several semiconductor devices located in parallel to one another, and the bars 14a, 14b, 14c, 14d are part of a common drain connection for each semiconductor device. The number of bars 14a, 14b, 14c, 14d may vary, depending on how many semiconductor devices are used. The insert 12 also includes a main body 16, and each of the bars 14a, 14b, 14c, 14d extend from the main body 16. There are several extensions 18a, 18b, 18c, 18d which are integrally formed as part of and protrude from the corresponding bars 14a, 14b, 14c, 14d, which are used for providing the various connections described.

Referring to FIGS. 4A-5, also integrally formed as part of the main body 16 is a fastening bar 20 having a threaded aperture 22. The bars 14b, 14c, 14d have a corresponding threaded aperture as well. The first bar 14a is generally L-shaped, and also includes a threaded aperture 24, as well as a cylindrically shaped extension 56, where the cylindrically shaped extension 56 includes a bore for a soldered pin connection. There are additional threaded apertures 26 formed as part of the main body 16, where the threaded apertures 22,24,26 are used for connecting the main body 16 to various components of the circuit board assembly 10.

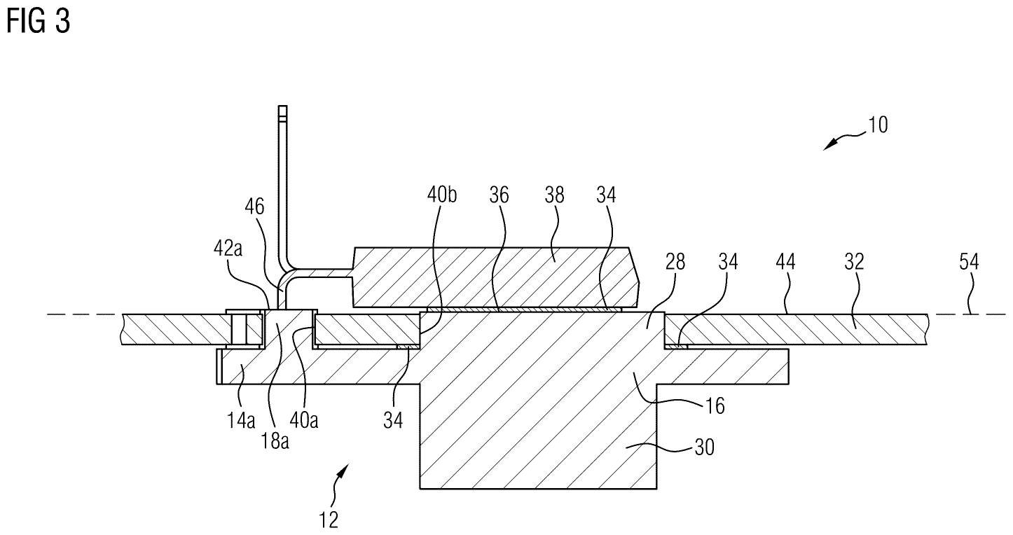

Referring to FIGS. 3-5, the insert 16 also includes a first protrusion 28 and a second protrusion 30. The first protrusion 28 extends away from the main body 16 in a first direction, and the second protrusion 30 extends away from the main body 16 in a second direction.

Referring now to FIG. 3, the insert 12 is mounted to a printed circuit board (PCB) 32 using a connecting material 34, which in this embodiment is a sintering paste or sintering compound 34. The sintering compound 34 is also used to connect at least one electrical component to an outer mounting surface 36 of the first protrusion 28. In the embodiment shown, the electrical component is a semiconductor device 38. The connection between the semiconductor device 38 and the insert 12 provides a first electrical and thermal connection, such that the semiconductor device 38 and the insert 12 are in electrical and thermal communication with one another.

The PCB 32 includes several apertures, and each extension 18a, 18b, 18c, 18d extends into a corresponding aperture of the PCB 32. Two of the apertures 40a,40b are shown in FIG. 3, where the extension 18a of the first bar 14a extends into the aperture 40a, and the first protrusion 28 extends into the aperture 40b of the PCB 32.

Each of the extensions 18a, 18b, 18c, 18d include a respective mounting surface 42a, 42b,42c,42d. When the insert 12 is mounted to the PCB 32 as shown in FIG. 3, the mounting surfaces 42a,42b,42c,42d of the extensions 18a, 18b, 18c, 18d and the outer mounting surface 36 of the first protrusion 28 are substantially in the same plane 54 relative to one another. The outer surface 44 of the PCB 32 may also be in the same plane 54 or have a small offset.

The semiconductor device 38 includes a connecting pin 46 which is connected to the mounting surface 42a of the extension 18a, providing a second electrical and thermal connection, or secondary connection, where the connecting pin 46 provides electrical and thermal communication between the semiconductor device 38 and the insert 12. The secondary connection may be a solder connection and is achieved by soldering an end of the connecting pin 46 to the mounting surface 42a.

The semiconductor device 38 also includes several connecting pins 58a,58b,58c. The connecting pin 58a is connected to the PCB 32 and acts as a source drain, the connecting pin 58b is connected to a driver is used as a kelvin source, and the connecting pin 58c is connected to a driver is used as a gate connection.

As mentioned above, the circuit board assembly 10 the bars 14a, 14b, 14c, 14d are part of a common drain connection for each semiconductor device mounted to the PCB 32, and each bar 14a, 14b, 14c, 14d has an extension 18a, 18b, 18c, 18d. In the embodiment shown, the mounting surfaces 42b,42c,42d of the extensions 18b, 18c, 18d are used for connection with more than one semiconductor device to increase ampacity and may vary in number.

Referring to FIGS. 1-2, the semiconductor device 38 also includes a housing 48, which in this embodiment is an overmold material. The housing 48 does not surround the entire semiconductor device 38. There is an area of exposed metal, which is used as a mounting surface 50. The mounting surface 50 is an area of exposed metal which the sintering compound 34 connects to, connecting the semiconductor device 38 to the insert 12, such that the semiconductor device 38 is in electrical and thermal communication with the insert 12. There are also several areas 52 which are part of the housing 48 shown in FIG. 1, which protect various components of the semiconductor device 38.

Referring again to the Figs. generally, during operation, the first electrical connection between the semiconductor device 38 and the insert 12 is the primary connection between the semiconductor device 38 and the insert 12. The insert 12 also functions as a heat sink and dissipates heat from the semiconductor device 38 and the PCB 32. There may be conditions where during operation of the circuit board assembly 10, the primary connection fails, such as through inadequate connection between the semiconductor device 38 and the insert 12. This may be a result of degradation of the sintering compound 34. If the primary connection fails, the secondary connection between the connecting pin 46 and the mounting surface 42a of the extension 18a still provides electrical communication between the semiconductor device 38 and the insert 12. This secondary connection allows the circuit board assembly 10 to function in a “limp home” mode, where the circuit board assembly 10 maintains a minimum functionality. In an embodiment, the circuit board assembly 10 is used as part of an electric vehicle. When operating in “limp home” mode, the electric motor of the vehicle may continue to operate with a minimum amount of current consumption. Heat dissipation by the semiconductor device 38 is reduced since the amount of heat transferred through the connecting pin 46 which occurs during normal operation (i.e., when the primary connection is functioning properly) is reduced.

An aspect of the present invention is a circuit board assembly 10 having a PCB 32 and an insert 12 connected to the PCB 32. The insert 12 is connected to the PCB 32 using a primary connection and a secondary connection. The primary connection between the semiconductor device 38 and the insert 12 functions as a first electrical and thermal connection. In an embodiment, a sintering compound 34 is used to connect the semiconductor device 38 and the insert 12 to achieve the first connection. The sintering compound 34 may also be used to connect the semiconductor device 38 to a PCB 32. The secondary connection includes a connecting pin 46 of the semiconductor device 38 which is connected to a mounting surface 42a of an extension 18a, where the extension 18a is integrally formed as part of a bar 14a of the insert 12. Several additional extensions 18b, 18c, 18d are formed as part of corresponding bars 14b, 14c, 14d of the insert 12, and each of the extensions 18b, 18c, 18d have corresponding mounting surfaces 42b,42c,42d. The connecting pin 46 achieves an electrical and a minor thermal connection and provides electrical communication between the semiconductor device 38 and the insert 12. The PCB 32 also includes several apertures 40a,40b. Each extension 18a, 18b, 18c, 18d at least partially extends into a corresponding one of the apertures 40a, and another protrusion 28 of the insert 12 at least partially extends into another of the apertures 40b such that the mounting surfaces 42a, 42b,42c,42d of the extensions 18a, 18b, 18c, 18d, the outer mounting surface 36 of the first protrusion 28, and the outer surface 44 of the PCB 32 are substantially in the same plane 54 relative to one another. In an alternate embodiment, the PCB 32 may be offset relative to the plane 54. During operation, if the primary connection fails, the secondary connection between the connecting pin 46 and the mounting surface 42a of the extension 18a still provides electrical and thermal communication between the semiconductor device 38 and the insert 12.

1. A circuit board assembly, comprising:
an insert;
a printed circuit board, the insert connected to the PCB;
at least one semiconductor device;
a primary connection between the insert and the at least one semiconductor device; and
a secondary connection between the insert and the at least one semiconductor device;
wherein the secondary connection provides electrical and thermal communication between the at least one semiconductor device and the insert when the primary connection fails.

2. The circuit board assembly of claim 1, the primary connection between the insert and the at least one semiconductor device further comprising a sintered connection, wherein the insert and the at least one semiconductor device are in electrical and thermal communication with one another through the sintered connection.

3. The circuit board assembly of claim 1, the sintered connection further comprising a sintering compound connecting the insert and the at least one semiconductor device.

4. The circuit board assembly of claim 1, the secondary connection further comprising a limp-home function if the primary connection fails.

5. The circuit board assembly of claim 4, the secondary connection between the insert and the at least one semiconductor device further comprising a solder connection.

6. The circuit board assembly of claim 1, further comprising:
at least one protrusion integrally formed as part of the insert, the at least one protrusion being part of the primary connection; and
at least one aperture integrally formed as part of the PCB;
wherein the at least one protrusion at least partially extends into the at least on aperture when the insert is assembled to the PCB.

7. The circuit board assembly of claim 6, further comprising:
at least one bar integrally formed as part of the insert;
at least one extension integrally formed as part of the at least one bar, the extension being part of the secondary connection; and
a second aperture integrally formed as part of the PCB;
wherein the extension integrally formed as part of the at least one bar at least partially extends into the second aperture when the insert is assembled to the PCB.

8. The circuit board assembly of claim 7, wherein an outer mounting surface of the at least one protrusion, a mounting surface of the extension, and the outer surface of the PCB in the same plane relative to one another or with a small offset.

9. A method for providing multiple connections between an insert and at least one semiconductor device of a circuit board assembly, comprising the steps of:
providing an insert;
providing a printed circuit board (PCB); and
providing at least one semiconductor device;
connecting the insert to the PCB;
connecting the insert to the at least one semiconductor device such that there is a primary connection between the insert and the at least one semiconductor device, and a secondary connection between the insert and the at least one semiconductor device; and
operating the circuit board assembly using a limp-home function with the secondary connection if the primary connection fails.

10. The method of claim 9, further comprising; the steps of
providing at least one bar integrally formed as part of the insert;
providing at least one protrusion integrally formed as part of the insert, the at least one protrusion being part of the primary connection; and
providing at least one aperture integrally formed as part of the PCB;
providing at least one extension integrally formed as part of the at least one bar, the at least one extension being part of the secondary connection;
providing a second aperture integrally formed as part of the PCB; and
connecting the insert to the at least one semiconductor device such that such that the at least one protrusion at least partially extends into the at least one aperture, the extension integrally formed as part of the insert at least partially extends into the second aperture, and an outer mounting surface of the at least one protrusion, a mounting surface of the extension, and the outer surface of the PCB are in the same plane relative to one another or with a small offset.

11. The method of claim 10, further comprising the steps of connecting the insert to the at least one semiconductor device using a sintering compound, forming the primary connection.

12. The method of claim 10, further comprising-the steps of connecting the insert to the at least one semiconductor device using a connecting pin, forming the secondary connection.

13. The circuit board assembly of claim 2, the sintered connection further comprising a sintering compound connecting the insert and the at least one semiconductor device.

14. The circuit board assembly of claim 2, the secondary connection further comprising a limp-home function if the primary connection fails.

15. The circuit board assembly of claim 3, the secondary connection further comprising a limp-home function if the primary connection fails.

16. The circuit board assembly of claim 2, further comprising:
at least one protrusion integrally formed as part of the insert, the at least one protrusion being part of the primary connection; and
at least one aperture integrally formed as part of the PCB;
wherein the at least one protrusion at least partially extends into the at least on aperture when the insert is assembled to the PCB.

17. The circuit board assembly of claim 3, further comprising:
at least one protrusion integrally formed as part of the insert, the at least one protrusion being part of the primary connection; and
at least one aperture integrally formed as part of the PCB;
wherein the at least one protrusion at least partially extends into the at least on aperture when the insert is assembled to the PCB.

18. The circuit board assembly of claim 4, further comprising:
at least one protrusion integrally formed as part of the insert, the at least one protrusion being part of the primary connection; and
at least one aperture integrally formed as part of the PCB;
wherein the at least one protrusion at least partially extends into the at least on aperture when the insert is assembled to the PCB.

19. The circuit board assembly of claim 5, further comprising:
at least one protrusion integrally formed as part of the insert, the at least one protrusion being part of the primary connection; and
at least one aperture integrally formed as part of the PCB;
wherein the at least one protrusion at least partially extends into the at least on aperture when the insert is assembled to the PCB.
